(19) United States
(12) Patent Application Publication
(10) Pub. No.: US 2021/0159352 A1
(43) Pub. Date: May 27, 2021

(54) PHOTOVOLTAIC MODULES AND METHOD OF MANUFACTURE THEREOF

(71) Applicant: CSEM CENTRE SUISSE D'ELECTRONIQUE ET DE MICROTECHNIQUE SA - RECHERCHE ET DÉVELOPPEMENT, Neuchâtel (CH)

(72) Inventors: Hengyu LI, Hauterive (CH); Jordi ESCARRE PALOU, Neuchâtel (CH); Karin SÖDERSTRÖM, Neuchâtel (CH); Xavier BULLIARD, Lussy (CH); Laure-Emmanuelle PERRET-AEBI, Neuchâtel (CH); Christophe BALLIF, Neuchâtel (CH)

(73) Assignee: CSEM CENTRE SUISSE D'ELECTRONIQUE ET DE MICROTECHNIQUE SA - RECHERCHE ET DÉVELOPPEMENT, Neuchâtel (CH)

(21) Appl. No.: 17/047,562

(22) PCT Filed: Apr. 16, 2018
(86) PCT No.: PCT/EP2018/059637

§ 371 Date: Oct. 14, 2020

(51) Int. Cl. H01L 31/048; H01L 31/049; H01L 31/054; H01L 31/18

(52) U.S. Cl. CPC H01L 31/0481; H01L 31/186; H01L 31/054; H01L 31/049

(57) ABSTRACT

Photovoltaic module comprising:
a front sheet arranged on a light incident side of said photovoltaic module;
a back sheet arranged on an opposite side of said photovoltaic module to said front sheet;
a photovoltaic conversion device disposed between said front sheet and said back sheet;
at least one front encapsulation layer disposed between said photovoltaic conversion device and said front sheet; wherein said front encapsulation layer comprises pigment particles distributed therein

### TECHNICAL FIELD

The present invention relates to the technical field of photovoltaic modules. More particularly, it relates to coloured photovoltaic modules particularly suited for building-integrated applications, as well as to methods of manufacture thereof.

### STATE OF THE ART

The natural colour of photovoltaic (PV) devices, also referred to as solar cells or solar panels, tends to be near black, often with a purple or indigo tint, with a clearly-defined pattern of the individual cells being visible. When such PV devices are mounted on buildings, they can be unsightly, and it is often unacceptable to use them directly as building cladding for this reason.

In order to overcome this issue, coloured PV devices have been proposed, which enable their integration into the structure of a building, notably as exterior cladding.

Document U.S. Pat. No. 9,281,186 discloses a film placed on the front sheet of the PV device to modify the appearance of the module. However, this film requires a specific profile which necessitates alignment with the geometry of the individual PV cells making up the module, and relies on a complex design involving facets in the front sheet and embedded elements in the inactive part of the module.

US 2014/326292 discloses a PV device comprising a graphic film placed inside the module. This film is printed with a colour or texture, and requires a selective reflector layer to limit the impact of the film on the efficiency of the module.

U.S. Pat. Nos. 9,276,141 and 8,513,517 disclose decorative film overlays placed on or within a PV module.

EP2793271 describes a white photovoltaic module in which an interference filter is formed on an intermediate layer deposited on the light-incident side of the photovoltaic module so as to reflect a certain amount of light over the whole visible spectrum. Specialised equipment and techniques are required to produce this interference filter.

However, all of these prior art solutions are either complex, or require extra layers to be applied to modules. Essentially, for each additional layer added to a module, the risk of delamination of the module increases since there are more interfaces between layers which can separate. Furthermore, special manufacturing techniques or equipment may be required.

The aim of the present invention is thus to at least partially overcome the above-mentioned drawbacks of the prior art.

### DISCLOSURE OF THE INVENTION

More specifically, the invention relates to a photovoltaic module comprising:
a front sheet arranged on a light incident side of said photovoltaic module, made of e.g. glass, transparent ceramic, polymer or other suitable transparent material;
a back sheet arranged on an opposite side of said photovoltaic module (1) to said front sheet, the back sheet being made of e.g. glass, metal, polymer, ceramic or other material;
a photovoltaic conversion device disposed between said front sheet and said back sheet, the PV device being of any convenient type;
at least one front encapsulation layer disposed between said photovoltaic conversion device and said front sheet, the front encapsulation layer being made of a thermoplastic or cross-linkable polymer such as EVA, polyolefin or similar. A back encapsulant between the PV conversion device and the back sheet can also be provided, if required.

According to the invention, the front encapsulation layer comprises pigment particles distributed therein. These particles give a coloration to the module making it suitable for use e.g. as building cladding, and furthermore scatter a certain amount of incoming light which helps to hide the structure of the photovoltaic conversion device. Furthermore, no special manufacturing techniques are required since the PV module can be assembled with standard lamination devices, and using standard front sheet forms without special features such as textures, structuration or similar.

Advantageously, at least some of said pigment particles have a diameter ranging from 100 nm to 1 μm, preferably 300-700 nm, more preferably 400-600 nm. The diameter of the particles can be optimised for the desired optical properties of the front encapsulant layer. Likewise, the pigment particles can be provided in said front encapsulation layer in a mass concentration ranging from 0.01 to 10 parts per hundred of the resin forming the front encapsulation layer, which can again be tuned to optimise the desired properties.

The pigment may comprise at least one of titanium dioxide, zinc oxide, an oxide of iron, a complex sulphur-containing sodium silicate, Prussian blue or any other convenient pigment.

Advantageously, the photovoltaic module may further comprise an interior front sheet and interior front encapsulant layer situated between the front encapsulant and the photovoltaic conversion device. As a result, the module of the invention may be made simply by laminating the front encapsulant and front sheet onto a pre-existing, prefabricated PV module. The module of the invention can thus be fabricated to order based on existing, commercially-available modules.

Advantageously, a graphic film printed with an image, pattern or similar may be disposed on the light incident side of said front sheet. The coloured front encapsulant hence provides a uniform background colour (which may e.g. be white) for providing good contrast with the graphic film.

The invention also relates to a method of manufacturing a photovoltaic module comprising the steps of:
providing a lamination device such as a heated vacuum bag laminator or other suitable device;
disposing in said lamination device a layer stack (31) comprising:
a front sheet intended to be arranged on a light incident side of said photovoltaic module (1), the front sheet being made of e.g. glass, transparent ceramic, polymer or other suitable transparent material;
a back sheet intended to be arranged on an opposite side of said photovoltaic module to said front sheet, the back sheet being made of e.g. glass, transparent ceramic, polymer or other suitable transparent material;
a photovoltaic conversion device of any convenient form disposed between said front sheet and said back sheet;
at least one front encapsulation layer of suitable thermoplastic or cross-linkable polymer disposed between said photovoltaic conversion device and said front sheet, said front encapsulation layer comprising pigment particles distributed therein. It is noted that a rear encapsulant may also be provided between the PV conversion device and the back sheet if desired.
applying heat and pressure to said layer stack so as to assemble it into said photovoltaic module by means of fusing and/or cross-linking the encapsulation layer(s).

The particles give a coloration to the module making it suitable for use e.g. as building cladding, and furthermore scatter a certain amount of incoming light which helps to hide the structure of the photovoltaic conversion device. Furthermore, no special manufacturing techniques are required since the PV module can be assembled with a standard lamination process, and using standard front sheets without special features such as textures, structuration or similar.

In an alternative process, the method of manufacturing a photovoltaic module comprises the steps of
providing a lamination device such as a heated vacuum bag laminator or other suitable device;
disposing in said lamination device a layer stack comprising:
a prefabricated photovoltaic module;
at least one front encapsulation layer disposed on a side of said prefabricated photovoltaic module intended to receive incident light, said front encapsulation layer comprising pigment particles distributed therein;
a front sheet arranged on a light incident side of said at least one front encapsulation layer;
applying heat and pressure to said layer stack so as to assemble it into said photovoltaic module by fusing and/or cross-linking the encapsulant material.

The advantages of the present invention can thus be applied to pre-existing, prefabricated PV modules. The module of the invention can thus be fabricated to order based on existing, commercially-available modules. This is particularly efficient since coloured modules can then easily be fabricated to order based on a stock of standard, commercially-available modules.

Advantageously, said layer stack further comprises a graphic film disposed on said light incident side of said front sheet. The graphic film can thus be incorporated directly into the module during lamination. Alternatively, it can be applied later, after lamination.

Advantageously, at least some, preferably at least 50% or even at least 75%, of said pigment particles have a diameter ranging from 100 nm to 1 μm, preferably 300-700 nm, more preferably 400-600 nm. The diameter of the particles can be optimised for the desired optical properties of the front encapsulant layer. Likewise, the pigment particles can be provided in said front encapsulation layer in a mass concentration ranging from 0.01 to 10 parts per hundred of resin, which can again be tuned to optimise the desired properties.

Advantageously, said pigment comprises at least one of titanium dioxide, zinc oxide, an oxide of iron, a complex sulphur-containing sodium silicate, or Prussian blue.

Advantageously, said front encapsulation layer is manufactured by mixing said pigment particles with a base resin, and extruding said front encapsulation layer as a film.

### BRIEF DESCRIPTION OF THE DRAWINGS

Further details of the invention will appear more clearly upon reading the description below, in connection with the following figures which illustrate:

FIG. 1: a schematic cross-sectional view of a photovoltaic module according to the invention;

FIG. 2: a schematic cross-sectional view of a further photovoltaic module according to the invention;

FIG. 3: a schematic cross-sectional view of part of a photovoltaic module according to the invention provided with a graphic film;

FIG. 4: a schematic representation of the manufacture of a photovoltaic module according to the invention by means of a lamination device;

FIGS. 5-8: graphs of experimental results obtained with photovoltaic modules according to the invention; and

FIG. 9: a schematic representation of a building structure provided with a photovoltaic module according to the invention.

### EMBODIMENTS OF THE INVENTION

It should be noted in the following that, unless explicitly stated that a particular layer is disposed directly on the adjacent layer, it is possible that one or more intermediate layers can also be present between the layers mentioned. As a result. “on” should be construed by default as meaning “directly or indirectly on”. Furthermore, patterning of certain layers, connectors and so on are not represented since they are well-known to the skilled person.

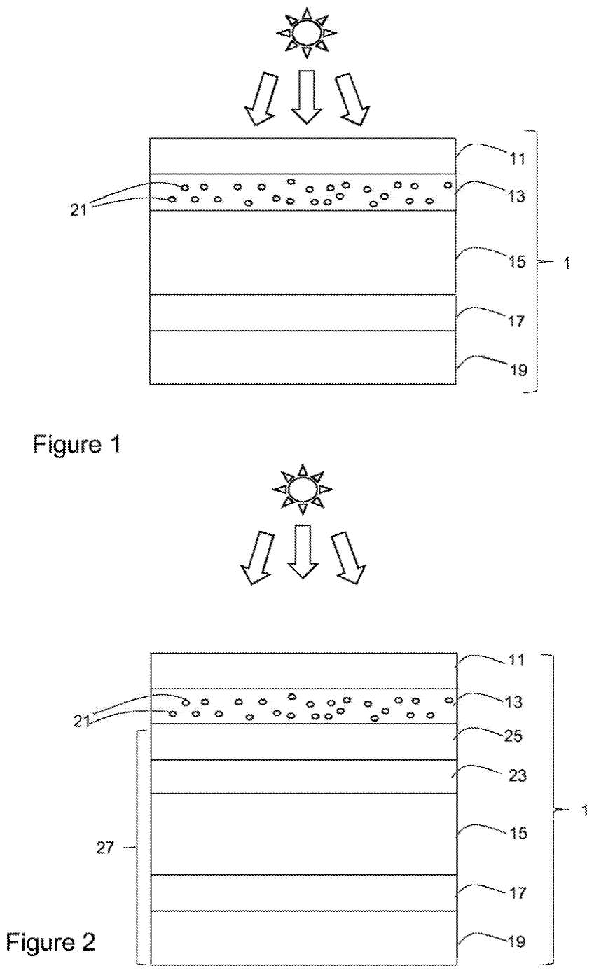

FIG. 1 illustrates a first embodiment of a photovoltaic (PV) module 1 according to the invention.

This module 1 comprises a front sheet 11, on the light incident side of the module 1, intended to be illuminated when in use (as indicated in the figures by means of a sun symbol), and a back sheet 19, on the opposite side of the module 1 to the front sheet 11. The front sheet may be glass, transparent ceramic, polymer or any other convenient substantially transparent material, and the back sheet may be metal, glass, ceramic, polymer or any other convenient material. The front sheet 11 may be structured, and may be provided with coatings.

Situated between the front and back sheets is a photovoltaic conversion device 15 comprising one or more PV cells comprising NIP. PIN, NP or PN junctions, patterned and interconnected as is generally known. The PV cells may be based on thin-film silicon, crystalline silicon, germanium, perovskite, dye-sensitised cells, or any other type of PV technology adapted to generate electrical power from light impinging on the light-incident side of the PV module 1.

The PV conversion device 15 is encapsulated on its front side by a front encapsulant layer 13, which seals it to the front sheet 11, and on its back side by a rear encapsulant layer 17. This latter seals the PV conversion device 15 to the back sheet 19, although it may indeed itself form the rear sheet. The encapsulants can be standard substances such as polyolefin, EVA (ethylene-vinyl acetate), ionomer, polyvinyl butyral, modified fluoropolymer or similar. Each of the encapsulant layers 13, 17 is typically between 200 μm and 1 mm thick. Furthermore, multiple front encapsulation layers 13 can be stacked on top of each other. In the case of a transparent (e.g. glass) or non-dark-coloured back sheet, the rear encapsulant layer 17 may be coloured or pigmented with a dark colour (e.g. black, dark brown, dark blue or similar) in order to help disguise interconnects and structuring present in the module.

It should be noted that other intermediate layers may be provided between the illustrated layers, and that the layers do not have to be flat and can describe curves or more complex surfaces.

According to the invention, the front encapsulant 13 comprises pigment particles 21 incorporated therein. In the case of multiple front encapsulant layers, one or more of these may comprise pigment particles, in the same or different concentrations, and comprising the same or different pigments.

These pigment particles 21 are represented highly schematically, and at least some, preferably at least 50%, further preferably at least 75% (or even substantially all) of the particles typically have a size ranging from 100 nm to 1 μm, most notably from 300-700 nm, and most particularly from 400-600 nm. It is noted that pigment particles are discrete particles, which are distinct from a colorant dispersed at molecular level in the encapsulant or an encapsulant made from an already coloured material.

A wide variety of pigments can be used, provided that they are chemically stable, are stable under prolonged ultraviolet light exposure either alone or in combination with an appropriate UV stabiliser such as Hindered Amine Light Stabilizers (HALS), hydroxyphenylbenzotriazole, oxanilides, benzophenones, benzotrazoles, hydroxyphenyltriazines and so on. As examples of suitable pigments, titanium oxide or zinc oxide particles may be used to generate a white colour. Yellow, orange, red and brown colours can be generated by using various iron oxides such as Fe₂O₃ for red ochre, or FeO(OH) for yellow. Blues can be generated e.g. by means of a complex sulphur-containing sodium silicate or Prussian blue.

The pigment particles 21 can be provided in concentrations ranging from 0.01 to 10 parts per hundred of the resin (phr) serving as the basis for the front encapsulation layer 13. More particularly, 0.1 to 5 phr, even more particularly 0.1-1 phr of pigment particles 21 can be used, depending on the thickness of the front encapsulation layer 13 thickness, thinner encapsulant layers typically benefitting from higher concentrations of pigment particles 21.

The pigment particles 21 absorb part of the visible light incident on the PV device 1 so as to generate the desired colour, and also diffuse light which provides a homogeneous colour and helps to hide the various features of the PV conversion device 15 such as its patterning, the tracks of electrical interconnections between the individual cells, the edges of the individual cells, the colour mismatches between the individual cells and the rear encapsulant 17 and/or backsheet 19, and so on.

This scattering effect is particularly advantageous over simply providing a front encapsulant which is coloured by means of a colorant dispersed therein at a molecular level, since such a colourant results in a much greater degree of optical transparency due to the lack of light scattering and hence does not hide the various features of the PV conversion device 15 as described above.

Furthermore, the scattering effect helps to diffuse the light that passes through the front encapsulant 13 and enters into the photovoltaicaly-active parts of the PV conversion device 15, increasing the average path length of light through the cell, in a manner similar to a conventional diffusion element incorporated in a PV module 1 on the light-incident side of the PV conversion device 15. Of course, the overall efficiency is reduced in proportion to the light reflected or scattered back towards the light-incident side of the PV device.

The size of the pigment particles 21 can be tuned to increase the transmittance in the infrared range for PV conversion devices 15 which are sensitive to IR light, and interference can be generated between the pigment particles 21 to give shiny, shimmering, or rainbow effects by optimising the pigment particle size and their density in the front encapsulant layer 13.

In respect of the manufacture of the front encapsulant layer 13, the required quantity of pigment particles 21 can simply be mixed in with the base resin or resin precursor which will form the encapsulant layer 13. If required, an appropriate UV stabiliser (as mentioned above) can also be incorporated into the resin at the same time. This can then be extruded as normal, without any special equipment or techniques.

As a result of this construction, a coloured fritted front glass (or similar) is no longer required as a front sheet 11, and the invention can thus be carried out without specialised equipment and the PV modules 1 can be assembled in conventional lamination devices (see below).

FIG. 2 represents another embodiment of a PV module 1 according to the invention. In this variant, front encapsulant layer 13 and front sheet 11 have been laminated onto the front of a pre-existing prefabricated PV module 27. As a result, the final PV module 1 according to the invention also comprises an internal front sheet 25 and an internal front encapsulant layer 23, since these layers are already present in the pre-existing prefabricated PV module 27. The remaining layers 15, 17 and 19 are comprised by the prefabricated PV module, are as described above and need not be described again.

This arrangement permits bringing the advantages of the present invention to any commercially-available PV module by retrofitting a front encapsulant layer 13 and front sheet 11 on to the existing module. This is also particularly advantageous since it makes it easier to produce a variety of different modules 1 according to the end-user's requirements. In essence, the manufacturer can maintain a stock of prefabricated standard PV modules 27, and then laminate thereupon the front encapsulant layer 13 and front sheet 11 according to requirements, either selecting an appropriately-coloured front encapsulant layer 13 from stock, or manufacturing it to order.

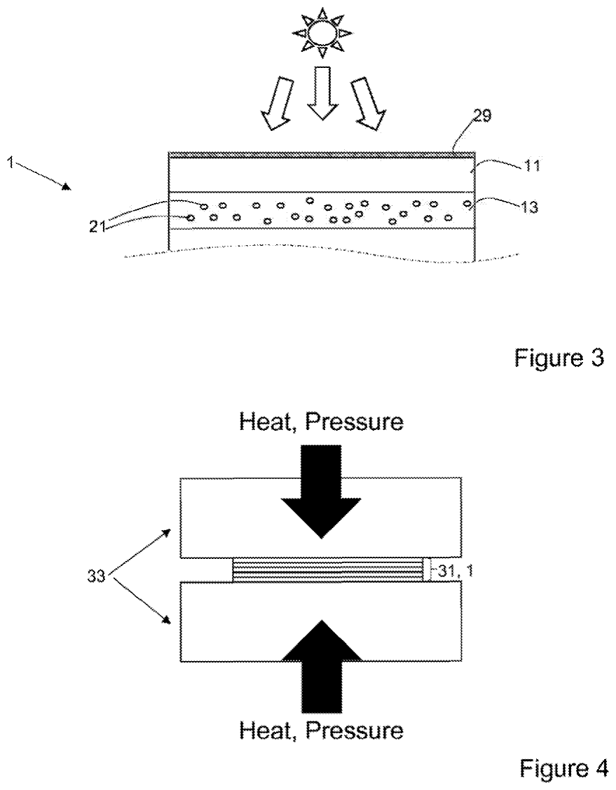

FIG. 3 partially illustrates a further variant of a PV module 1 according to the invention, comprising a graphic film 29 applied to the light-incident side of the front sheet 11. This graphic film 29 may, for instance, be a polymer film such as a commercially-available PET film, upon which an image, a pattern or similar has been printed by means of any convenient technique. The graphic film 29 may be applied either during lamination (see below), or after manufacture of the otherwise-finished PV module 1.

The graphic film 29 may be applied to either the embodiment of FIG. 1 or of FIG. 2, and as a result the rest of the PV module 1 has not been represented in FIG. 3.

Alternatively, in a non-illustrated embodiment, the graphic film 29 can be laminated between the front encapsulant 13 and the front sheet 11.

As further possibilities which can be applied as appropriate in any of the above embodiments, a polymer layer containing the pigment particles described above may be used as a front sheet 11 e.g. directly in contact with the front encapsulant 13, or may be provided as an extra layer on top of a glass or polymer front sheet. In such cases, the front encapsulant 13 may contain particles according to the invention, or may be conventional. A particularly advantage resin for this particle-containing layer is a fluroolefin such as Lumiflon (from Asahi Glass Co. Ltd), however other polymers are possible.

FIG. 4 represents schematically a method of manufacturing a PV module 1 according to the invention.

A layer stack 31 comprising at least the layers 11, 13, 15, 17 and 19, together with any other layers present, is assembled in a lamination device 33. In the case of the embodiment of FIG. 2, the layer stack comprises a pre-fabricated PV module 27, upon which front encapsulant layer 13 and front sheet 11 (and any other desired layers) have been applied. It should be noted that the layer stack 31 can be assembled in the lamination device 33 either with the light-incident side of the final PV module facing downwards or facing upwards.

The lamination device may be a vacuum bag laminator, roller-type laminator, or any other convenient type. The lamination device 33 then applies heat and pressure, e.g. at a temperature of 140° C. to 180° C. and a pressure of up to 1 bar (typically 0.4 bar to 1 bar), for an appropriate length of time, which causes the various encapsulant layers to fuse and thereby to assemble the final PV module 1.

As a result, the PV module 1 according to the invention can be made in conventional PV processing equipment, without requiring specialised equipment.

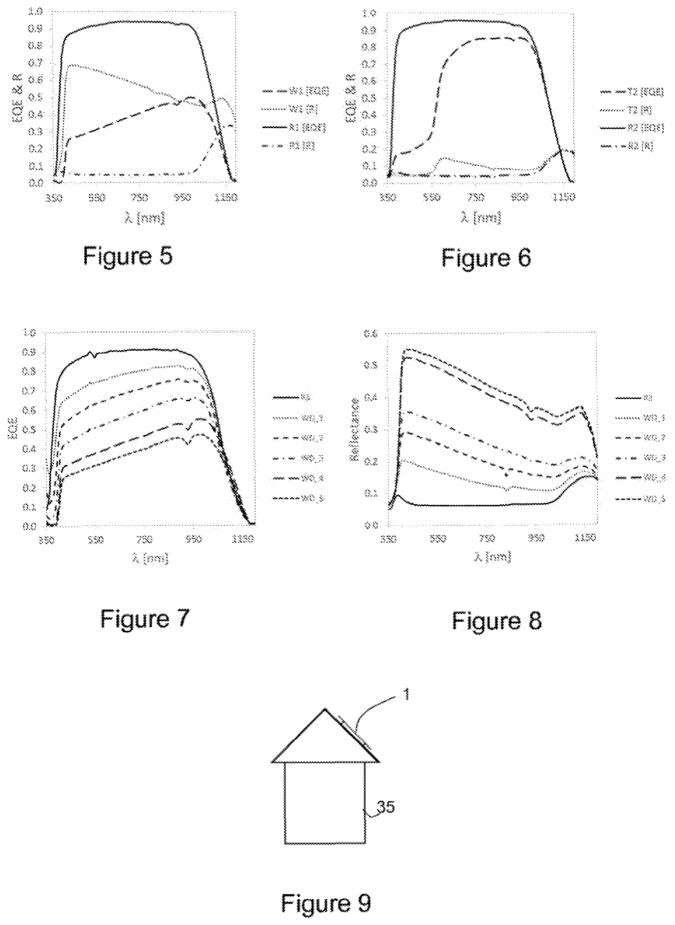

FIG. 5 illustrates a graph of experimental results obtained by manufacturing a PV module 1 according to the embodiment of FIG. 2, wherein the front encapsulant layer 13 was made with Dow Engage PV POE XUS 38660.00 polyolefin-based base resin, 1 phr DuPont Ti-Pure R-960 titanium dioxide-based pigment, with no further additives. Median pigment particle size was 500 nm.

The pigment particles were added and mixed manually with the base resin and extruded at 170° C. by means of a twin-screw extruder to obtain a white cross-linkable polyolefin film with a thickness of 0.85 mm.

The resulting white front encapsulation sheet was combined with a 50 μm thick ETFE front sheet, and laminated onto a prefabricated PV module at a temperature of 165° C. and pressure of approximately 1 bar (±0.99 bar) for 720 seconds.

The metal connections of the PV module were blackened and the backsheet 19 was also black coloured to reduce contrast.

The graph of FIG. 5 illustrates the external quantum efficiency (EQE) and reflectance (R) over the wavelength range of 350 nm to just over 1150 nm, for the PV module 1 according to the invention as described immediately above (W1), and contrasted with a reference cell with the same construction but built using a clear front encapsulant layer 13 (R1). As can be seen, the EQE fell and the reflectance increased over a wide bandwidth of wavelengths of light.

Furthermore, the cell performance and colour expressed in “Lab” colour space coordinates were also measured, the results of which appear in the following table:

| | Module | | | | |
|---|---|---|---|---|---|
| | Current | Relative | | | |
| | J_{SC} | Performance | Colour | Colour | Colour |
| ID | [mA/cm²] | ΔJ_{SC} [%] | L | a | b |
| R1 | 39.0 | — | 25.3 | 0.46 | −2.70 |
| W1 | 16.5 | −57.7 | 84.8 | −1.39 | −2.44 |

As can be seen from the table, the module 1 thus constructed has a white colour, with current losses of approximately 58%.

FIG. 6 illustrates a graph of experimental results obtained by manufacturing another PV module 1 according to the embodiment of FIG. 2, wherein the front encapsulant layer 13 was made with ExxonMobil Escorene Ultra UL 00728CC EVA copolymer base resin, with 0.05 wt. % of Scholz Red 110M pigment particles dispersed therein.

The red pigment particles were mixed with the base resin manually, which was then extruded at 95° C. to create a 0.9 mm thick film of front encapsulant. This was then combined with a 100 μm thick ETFE front sheet and laminated at 150° C. at a pressure of substantially 1 bar for 720 seconds. As per the previous example, the metal connections were blackened and a black coloured backsheet 19 was used.

The resulting PV module has a terracotta colour particularly suitable for mounting on roofs in areas where terracotta tiles are common, and the graph of FIG. 6 again shows the EQE and reflectivity results obtained for this PV module (T2) compared to a similarly-constructed reference module (R2) using conventional clear front encapsulant. In this case, the EQE of the terracotta module T2 is only significantly diminished below about 650 nm wavelength, and the reflectance profile only rises slightly above about 600 nm wavelength.

Furthermore, the performance and colour results are expressed in the following table:

| | Current | Relative | | | |
|---|---|---|---|---|---|
| | J_{SC} | Performance | Colour | Colour | Colour |
| ID | [mA/cm²] | ΔJ_{SC} [%] | L | a | b |
| R2 | 38.9 | — | 24.0 | 1.65 | −3.95 |
| W2 | 27.8 | −28.5 | 34.6 | 16.55 | 16.24 |

Current losses are limited to 28.5%, which compares favourably to the 57.7% losses measured for the previous white module.

FIG. 7 illustrates a graph of EQE, and FIG. 8 illustrates a graph of reflectance, with respect to wavelength of light obtained by PV modules constructed according to FIG. 1.

In this series of experiments, various PV modules according to the invention were constructed according to the structure of FIG. 1, comprising various front encapsulants made up from one or more of the following layers:

| ID | Pigment concentration | Thickness [mm] |
|---|---|---|
| D_1 | 0.05 wt % | 0.55 |
| D_2 | 0.15 wt % | 0.55 |
| D_3 | 0.25 wt % | 0.55 |

The base resin was Polidemme FE1252 EP modified polyolefin from Padanaplast, and the pigment particles were Ti-Pure R-960 from DuPont, as mentioned above. The base resin and pigment were first compounded on a twin-screw extruder at 170° C. and pelletised. Subsequently, the pellets were extruded at 170° C. on a single-screw extruder to form films with the stated thickness. The pigmentation of these films was adapted so as to give alight diffusive effect and a white colour, and the following modules were ID Front encapsulant

| ID | Front encapsulant |
|---|---|
| R3 | Clear (reference) |
| WD_1 | D_1 |
| WD_2 | D_2 |
| WD_3 | D_3 |
| WD_4 | D_2 + D_4 (stacked) |
| WD_5 | D_3 + D_3 (stacked) |

Considering the graphs of FIGS. 7 and 8, the PV module WD_3 represents a good tradeoff between performance and aesthetics.

The same PV/modules were also subjected to a performance test and a 380-780 nm reflectance test, and the results are reproduced below.

| | Current | Relative | Reflectance |
|---|---|---|---|
| | J_{SC} | performance | R_{380-780 nm} |
| ID | [mA/cm²] | ΔJ_{SC} [%] | [%] |
| R3 | 36.2 | — | 6.3 |
| WD_1 | 31.7 | −12.4 | 15.6 |
| WD_2 | 27.9 | −22.9 | 23.7 |
| WD_3 | 23.3 | −35.6 | 29.8 |
| WD_4 | 18.7 | −48.3 | 46.1 |
| WD_5 | 15.8 | −56.3 | 48.8 |

As a final example, three modules according to the embodiment of FIG. 1 with an applied image layer 29 according to FIG. 3 were fabricated. A reference module again comprised a clear front encapsulent 13, and then two others with front encapsulant layers 13 according to WD_3 and WD_4 as described above were also fabricated. The image graphic on the reference module was hardly visible, whereas it was clearly visible on the other two.

The performance results of the three modules are reproduced below:

| | | Relative | | Relative |
|---|---|---|---|---|
| | Current | performance | | performance |
| | J_{SC} | for current | Power | for power |
| ID | [A] | [%] | [W] | [%] |
| Reference | 5.67 | — | 2.597 | — |
| WD_3 | 4.83 | −13.3 | 2.249 | −13.4 |
| WD_4 | 3.64 | −34.6 | 1.698 | −34.6 |

Again, the front encapsulant WD_3 represents a good compromise between aesthetics and power/current loss compared to an uncoloured reference.

Finally. FIG. 9 illustrates a photovoltaic module 1 according to the invention mounted on the roof of a building structure 35. Alternatively, the PV module 1 can be mounted to an exterior wall, or integrated into the structure of the wall and/or roof, e.g. as cladding. In general terms, the PV module 1 can be mounted on or in the structure of the building 35.

Although the invention has been described in terms of specific embodiments, variations thereto are possible without departing from the scope of the invention as defined in the appended claims.

1-14. (canceled)

15. Photovoltaic module comprising:
a front sheet arranged on a light incident side of said photovoltaic module;
a back sheet (19) arranged on an opposite side of said photovoltaic module to said front sheet;
a photovoltaic conversion device disposed between said front sheet and said back sheet;
at least one front encapsulation layer disposed between said photovoltaic conversion device (15) and said front sheet;
wherein said front encapsulation layer comprises pigment particles distributed therein.

16. Photovoltaic module according to claim 15, wherein at least some, preferably at least 50%, further preferably at least 75% of said pigment particles have a diameter ranging from 100 nm to 1 μm, preferably 300-700 nm, more preferably 400-600 nm.

17. Photovoltaic module according to claim 15, wherein said pigment particles are provided in said front encapsulation layer in a mass concentration ranging from 0.01 to 10 parts per hundred of resin.

18. Photovoltaic module according to claim 15, wherein said pigment comprises at least one of:
Titanium dioxide;
Zinc oxide;
An oxide of iron;
A complex Sulphur-containing sodium silicate.
Prussian blue

19. Photovoltaic module according to claim 15, further comprising an interior front sheet and interior front encapsulant layer situated between the front encapsulant and the photovoltaic conversion device.

20. Photovoltaic according to claim 15, further comprising a graphic film disposed on the light incident side of said front sheet.

21. Method of manufacturing a photovoltaic module comprising the steps of:
providing a lamination device;
disposing in said lamination device a layer stack comprising:
a front sheet intended to be arranged on a light incident side of said photovoltaic module;
a back sheet intended to be arranged on an opposite side of said photovoltaic module to said front sheet;
a photovoltaic conversion device disposed between said front sheet and said back sheet;
at least one front encapsulation layer disposed between said photovoltaic conversion device and said front sheet, said front encapsulation layer comprising pigment particles distributed therein;
applying heat and pressure to said layer stack so as to assemble it into said photovoltaic module.

22. Method of manufacturing a photovoltaic module comprising the steps of:
providing a lamination device;
disposing in said lamination device a layer stack comprising:
a prefabricated photovoltaic module;
at least one front encapsulation layer disposed on a light incident side of said prefabricated photovoltaic module, said front encapsulation layer comprising pigment particles distributed therein;
a front sheet arranged on a light incident side of said at least one front encapsulation layer;
applying heat and pressure to said layer stack so as to assemble it into said photovoltaic module.

23. Method according to claim 21, wherein said layer stack further comprises a graphic film disposed on said light incident side of said front sheet.

24. Method according to claim 21, wherein at least some of said pigment particles have a diameter ranging from 100 nm to 1 μm, preferably 300-700 nm, more preferably 400-600 nm.

25. Method according to claim 21, wherein said pigment particles are provided in said front encapsulation layer in a mass concentration ranging from 0.01 to 10 parts per hundred of resin.

26. Method according to claim 21, wherein said pigment comprises at least one of:
Titanium dioxide;
Zinc oxide;
An oxide of iron;
A complex Sulphur-containing sodium silicate.
Prussian blue

27. Method according to claim 21, wherein said front encapsulation layer is manufactured by mixing said pigment particles with a base resin, and extruding said front encapsulation layer as a film.

28. Building structure comprising at least one photovoltaic module according to claim 15.
